(19) United States
(12) Patent Application Publication
(10) Pub. No.: US 2022/0377888 A1
(43) Pub. Date: Nov. 24, 2022

(54) TRANSPARENT PACKAGE FOR USE WITH PRINTED CIRCUIT BOARDS

(71) Applicant: Honeywell Federal Manufacturing & Technologies, LLC, Kansas City, MO (US)

(72) Inventor: Louis Diamond, Kansas City, MO (US)

(73) Assignee: Honeywell Federal Manufacturing & Technologies, LLC, Kansas City, MO (US)

(21) Appl. No.: 17/579,974

(22) Filed: Jan. 20, 2022

Related U.S. Application Data
(60) Provisional application No. 63/191,194, filed on May 20, 2021.

(51) Int. Cl. H05K 1/11; H05K 1/02; H05K 1/03; H05K 1/09

(52) U.S. Cl. CPC H05K 1/11; H05K 1/0274; H05K 1/0306; H05K 1/09; H05K 2201/0338; H05K 2201/0108

(57) ABSTRACT

A blank package for mimicking an electronic component package comprises a body and a plurality of conductive pads. The body is formed from generally transparent electrically insulating material and has a top surface, a bottom surface, and a plurality of side surfaces. The bottom surface has a shape and dimensions that are similar to a bottom surface of the electronic component package. The conductive pads are formed from electrically conductive material and attached to the body, with each conductive pad corresponding to a successive one of the conductive pads of the electronic component package. Each conductive pad has features that are similar to features of the corresponding conductive pad of the electronic component package.

### RELATED APPLICATIONS

The current patent application is a regular utility patent application which claims priority benefit, with regard to all common subject matter, of earlier-filed U.S. Provisional Application titled “TRANSPARENT PACKAGE FOR USE WITH PRINTED CIRCUIT BOARDS”, Ser. No. 63/191,194, filed May 20, 2021. The Provisional Application is hereby incorporated by reference, in its entirety, into the current patent application.

### STATEMENT REGARDING FEDERALLY-SPONSORED RESEARCH OR DEVELOPMENT

This invention was made with Government support under Contract No.: DE-NA0002839 awarded by the United States Department of Energy/National Nuclear Security Administration. The Government has certain rights in the invention.

### FIELD OF THE INVENTION

Embodiments of the current invention relate to electronic component packages that are transparent and to transparent printed circuit boards.

### DESCRIPTION OF THE RELATED ART

Electronic circuitry production for devices such as TVs, computers, automotive control systems, smartphones, etc., often involves electrically connecting integrated circuit and discrete electronic component packages to a printed circuit board using solder, solder paste, and flux. The connection process often leaves behind residual solder, solder paste, and flux and may create dendrites, tin whiskers, and corrosion. Thus, the printed circuit board and component packages need to be cleaned. However, traditional cleaning processes may not sufficiently clean everything—particularly with leadless electronic component packages in which the solder connections are made on the bottom surface of the package and are covered by the package itself. One drawback is that there is no way to properly evaluate whether the electronic circuitry is being cleaned since in some cases the connections to be cleaned are hidden from view.

### SUMMARY OF THE INVENTION

Embodiments of the current invention address one or more of the above-mentioned problems and provide a blank package which includes a body formed from transparent material and a plurality of conductive pads that are shaped and positioned in a same manner as conductive pads on a functional component package to be mimicked or imitated by the blank package. A plurality of blank packages, each imitating a particular functional electronic component package, is mounted on the printed circuit board. The printed circuit board undergoes the standard electrical connection and cleaning processes. After each process, the printed circuit board may be visually inspected. Since the blank packages are transparent to visible light, any debris or residue beneath the body of each blank package can be observed so as to gauge the quality of the fabrication and cleaning processes.

An embodiment of the blank package broadly comprises a body and a plurality of conductive pads. The body is formed from generally transparent electrically insulating material and has a top surface, a bottom surface, and a plurality of side surfaces. The bottom surface has a shape and dimensions that are similar to a bottom surface of the electronic component package. The conductive pads are formed from electrically conductive material and attached to the body, with each conductive pad corresponding to a successive one of the conductive pads of the electronic component package. Each conductive pad has features that are similar to features of the corresponding conductive pad of the electronic component package.

Another embodiment of the current invention provides a method of forming a blank package that mimics an electronic component package. The method broadly comprises receiving functional electronic component package specifications including body dimensions and conductive pad sizes, shapes, and locations; forming a body of the blank package from transparent electrically insulating material, wherein the body includes a bottom surface having a shape and dimensions that are similar to a bottom surface of the electronic component package; and forming a plurality of conductive pads on the body from electrically conductive material, each conductive pad corresponding to a successive one of the conductive pads of the electronic component package and each conductive pad having features that are similar to features of the corresponding conductive pad of the electronic component package.

Another embodiment of the current invention provides a transparent printed circuit board for mimicking an actual printed circuit board. The transparent printed circuit board broadly comprises a body, a plurality of package footprints, and a plurality of conductive traces. The body is formed from rigid, generally transparent electrically insulating material and has a top surface, a bottom surface, and a plurality of edges. The package footprints are formed from electrically conductive material and positioned on the body. The package footprints correspond to at least a portion of a plurality of package footprints of the actual printed circuit board.

Another embodiment of the current invention provides a method of forming a transparent printed circuit board to mimic an actual printed circuit board. The method broadly comprises receiving data regarding at least a portion of a placement of package footprints and routing of conductive traces for the actual printed circuit board; forming a body of the transparent printed circuit board from rigid, generally transparent electrically insulating material, the body having a top surface, a bottom surface, and a plurality of edges; forming a plurality of package footprints on the body corresponding to the package footprints of the actual printed circuit board; and forming a plurality of conductive traces on the body corresponding to the conductive traces of the actual printed circuit board.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF THE DRAWING FIGURES

Embodiments of the current invention are described in detail below with reference to the attached drawing figures, wherein:

FIG. 1A is a top view of a printed circuit board with a plurality of blank packages, constructed in accordance with various embodiments of the current invention, electrically connected thereto;

FIG. 1B is an upper perspective view of the printed circuit board with the blank packages;

FIG. 2A is a top view of the printed circuit board by itself;

FIG. 2B is an upper perspective view of the printed circuit board by itself;

FIG. 3A is a top view of one embodiment of the blank package;

FIG. 3B is an upper perspective view of the blank package;

FIG. 4A is a top view of another embodiment of the blank package;

FIG. 4B is an upper perspective view of the blank package;

FIG. 4C is a side view of the blank package;

FIG. 5A is a top view of another embodiment of the blank package which includes leads;

FIG. 5B is an upper perspective view of the blank package which includes leads;

FIG. 6A is a top view of another embodiment of the blank package which includes conductive pads that have a hatch pattern;

FIG. 6B is an upper perspective view of the blank package which includes conductive pads that have a hatch pattern;

FIG. 7A is a top view of another embodiment of the blank package which includes a bottom surface that has a rough finish;

FIG. 7B is an upper perspective view of the blank package which includes a bottom surface that has a rough finish;

FIG. 8 is a listing of at least a portion of the steps of a method of forming a blank package that mimics an electronic component package;

FIG. 9A is a top view of a transparent printed circuit board, constructed in accordance with various embodiments of the current invention, with a plurality of packages electrically connected thereto;

FIG. 9B is an upper perspective view of the transparent printed circuit board;

FIG. 10A is a top view of the transparent printed circuit board with a plurality of packages electrically connected thereto;

FIG. 10B is an upper perspective view of the transparent printed circuit board with the packages;

FIG. 11A is a bottom view of the transparent printed circuit board with a plurality of packages electrically connected thereto;

FIG. 11B is a lower perspective view of the transparent printed circuit board with the packages; and

FIG. 12 is a listing of at least a portion of the steps of a method of forming a transparent printed circuit board that mimics an actual printed circuit board.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

Relational terms, such as “above”, “below”, “upper”, “upward”, “downward”, “lower”, “top”, “bottom”, “outer”, “inner”, etc., along with orientation terms, such as “horizontal” and “vertical”, may be used throughout this description. These terms are used with reference to embodiments of the technology and the positions and orientations thereof shown in the accompanying figures. Embodiments of the technology may be positioned and oriented in other ways. Therefore, the terms do not limit the scope of the current technology.

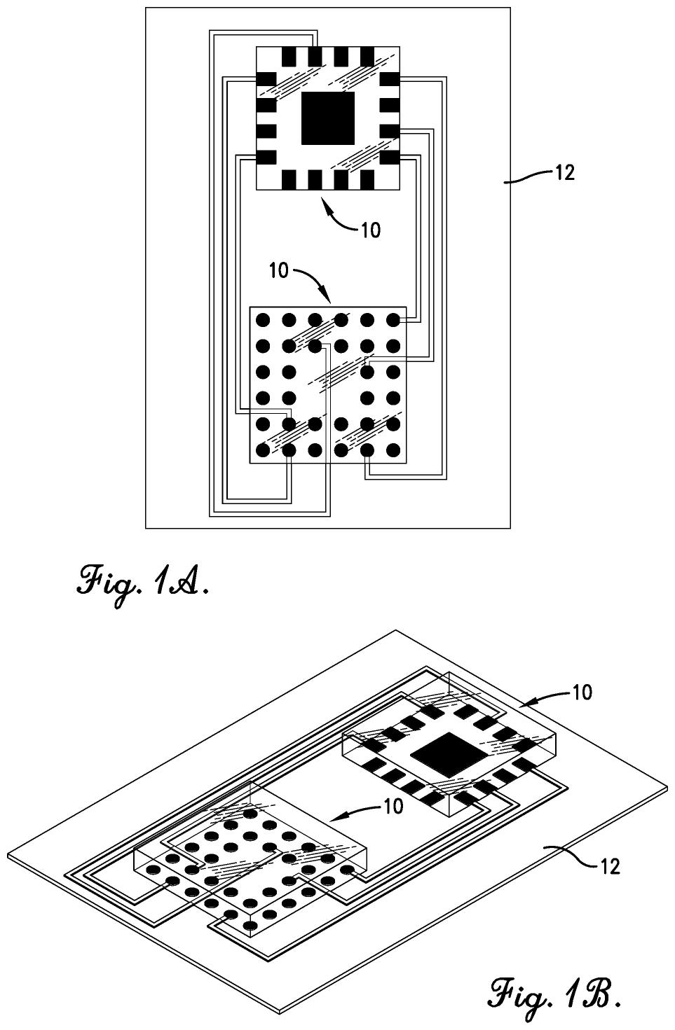

Referring to FIGS. 1A and 1B, a plurality of blank packages 10, constructed in accordance with various embodiments of the current invention, is shown. The blank packages 10 are transparent and provide for visual inspection of a printed circuit board (PCB) 12 to which the blank packages 10 are connected. Each blank package 10 includes no electric circuitry and performs no computational or logical operation. The purpose and/or function of the blank package 10 is to mimic the electrodes or electrical connectivity architecture of a functional integrated circuit or discrete electronic component package.

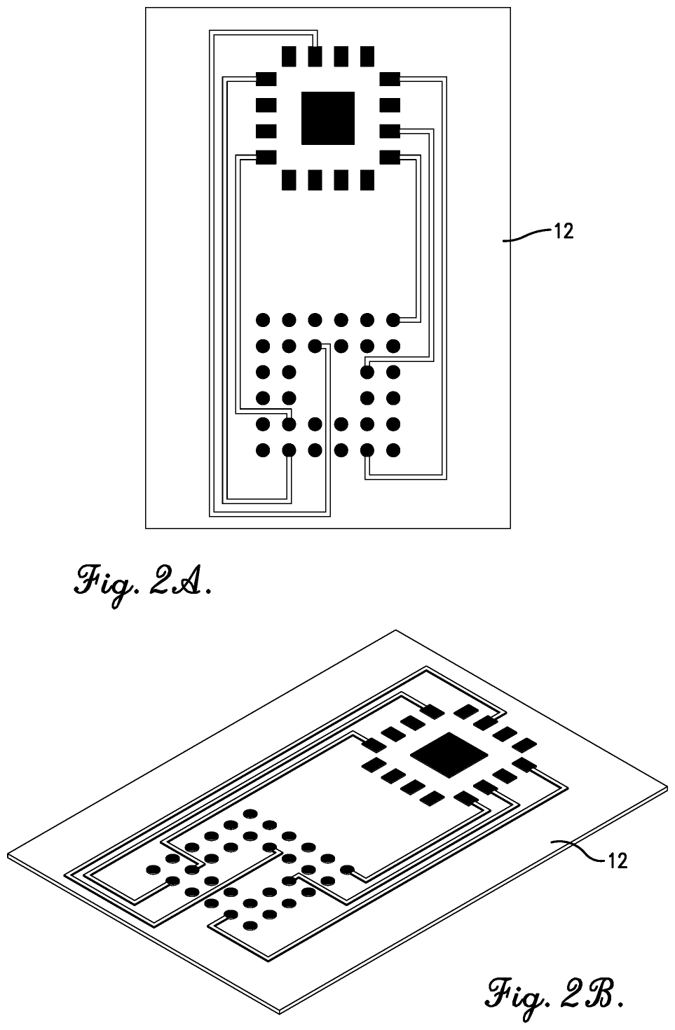

Referring to FIGS. 1A, 1B, 2A, and 2B, the PCB 12, or printed wiring board, may be of generally known construction with a first side and an opposing second side. The PCB 12 may also include multiple electrically conductive layers with a top conductive layer placed on the first side, a bottom conductive layer placed on the second side, one or more inner conductive layers positioned between the first and second sides, and an insulating layer between each pair of adjacent conductive layers. The insulating layers, which in combination form a substrate, may be formed from rigidized material that includes various combinations of fiberglass, woven glass, matte glass, cotton paper, phenolic cotton paper, polyester, epoxies, epoxy resins, and the like. Alternatively, the insulating layers may be formed from a flexible polymer thin film material. Each conductive layer may include one or more conductive electronic signal traces, electric power or ground traces, one or more signal, power, or ground lands, full or partial power planes, or full or partial ground planes. The conductive layers may be formed from metals typically including copper, but also including nickel, aluminum, gold, silver, palladium, zinc, tin, lead, and the like. In addition, the PCB 12 may include plated through hole vias, blind vias, buried vias, and the like.

The exemplary embodiment of the PCB 12 shown in the figures includes a first package footprint and a second package footprint. The first package footprint includes the land (or pad) placement for a quad flat no lead (QFN) component package, and the second package footprint includes the land placement for a ball grid array (BGA) component package. In addition, the PCB 12 includes a plurality of conductive traces, each of which electrically connect one land of the first package footprint to one land of the second package footprint. The PCB 12 may also include land for discrete components in packages such as 805, 603, etc. Furthermore, the PCB 12 may include other surface or through-hole package footprints.

Referring to FIGS. 1A, 1B, 3A, 3B, 4A, 4B, and 4C, the blank package 10 broadly comprises a body 14 and a plurality of conductive pads 16. The body 14 is formed from generally transparent, or translucent, electrically insulating material including various types of glass, such as silicate glass or borosilicate glass. The body 14 is transmissive to light in the visible spectrum, i.e., ranging from approximately 400 nanometers (nm) to approximately 700 nm—meaning that visible light passes through the body 14. Preferably, the material of the body 14 is capable of withstanding high temperature. The body 14 is typically solid with a box structure having a top surface, a bottom surface, and a plurality of side surfaces. Generally, the bottom surface of the body 14 has a shape and dimensions that are the same as, or similar to, a bottom surface of the electronic component package that the blank package 10 is created to mimic or imitate. However, the body 14 may be configured to mimic or imitate nearly any geometry. Exemplary embodiments of the body 14 are approximately 1.1 millimeters (mm) thick.

The conductive pads 16 are positioned on the bottom surface of the body 14 and/or extend outward from one or more side surfaces of the body 14. Each conductive pad 16 corresponds to a successive one of the conductive pads of the electronic component package. Each conductive pad 16 also has a size, a shape, and a location which is the same as, or similar to, a size, a shape, and a location, respectively, of a corresponding conductive pad or electrode on the electronic component package that the blank package 10 is mimicking or imitating.

Each conductive pad 16 is formed from electrically conductive material such as metals and/or metal alloys. In some embodiments, the conductive pad 16 may be formed from a plurality of layers of metals and/or metal alloys, wherein a lowest layer may be formed from a metal or metal alloy that enhances adhesion with the body 14. In some embodiments, the conductive pad 16 may be formed from a stack of metals including titanium (in contact with the body 14), nickel, and gold. These metals render the conductive pad 16 to be solderable, to withstand the high temperatures of a solder reflow process, and to withstand the caustic chemical solutions of the cleaning process. In other embodiments, the conductive pad 16 may be formed from a stack of metals including titanium (in contact with the body 14), aluminum, titanium, nickel, and gold. This stack of metals provides the additional feature of the conductive pad 16 to include electrically conductive traces.

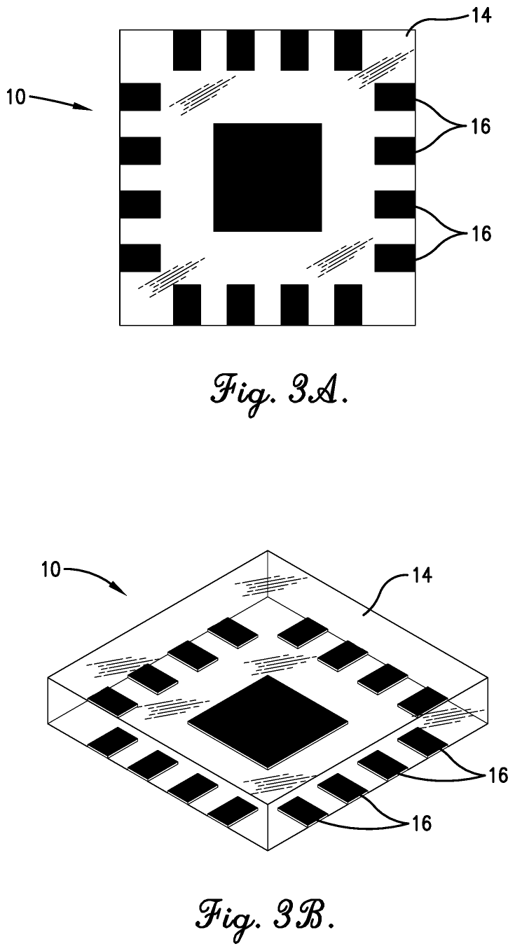

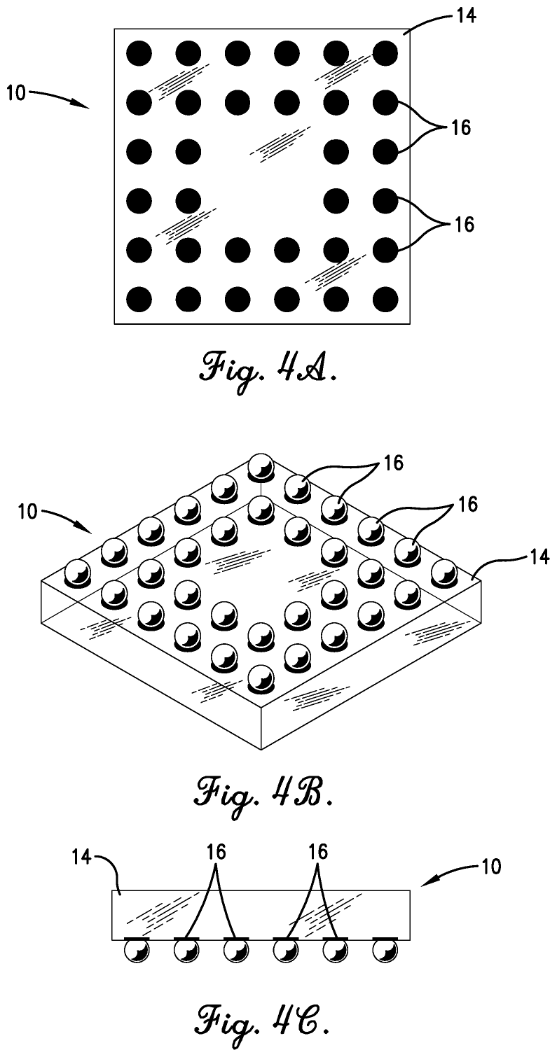

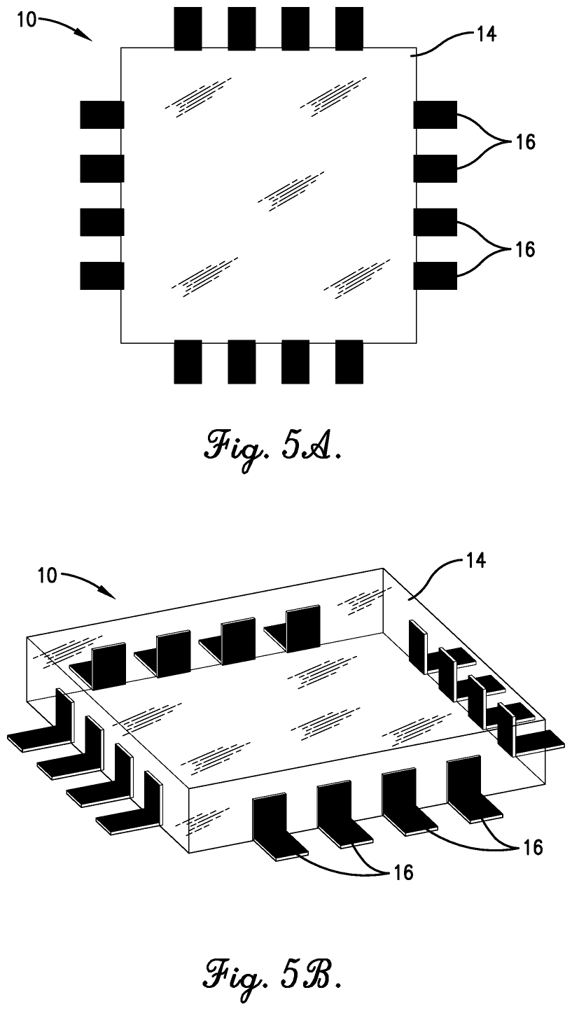

Exemplary blank packages 10 include a QFN package shown in FIGS. 3A and 3B, a BGA package with solder balls attached shown in FIGS. 4A, 4B, and 4C, and a quad flat package (QFP) shown in FIGS. 5A and 5B. Generally, the blank package 10 may be configured to mimic or imitate nearly surface mount technology package wherein pads or leads are positioned on the bottom surface of the package or leads extend outward from one or more side surfaces of the package. In addition, the blank package 10 may be configured to mimic or imitate and discrete component packages such as 805, 603, and the like. It is also possible that the blank package 10 may be configured to mimic or imitate through-hole packages.

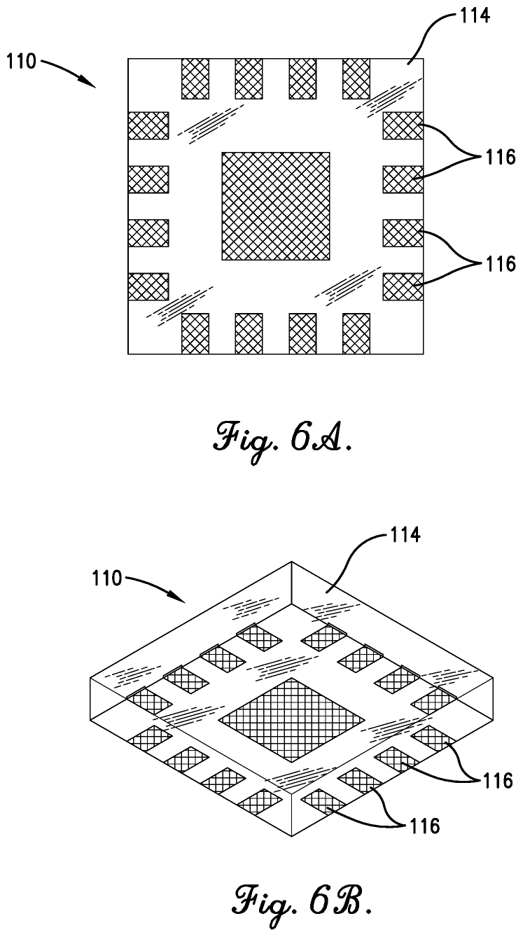

Referring to FIGS. 6A and 6B, other embodiments of the blank package 110 include a body 114 and a plurality of conductive pads 116. The body 114 is the same as, or substantially similar to, the body 14. The conductive pads 116 have the same, or substantially similar, size, shape, and position as the conductive pads 116. The primary difference between the conductive pads 116 and the conductive pads 16 is that at least a portion of the conductive pads 116 have a hatch pattern in the one or more layers of metal that form the conductive pad 116. That is, some conductive pads 116 include a plurality of narrow lanes or channels that extend across the conductive pad 116 fully along one or more dimensions in which the metal is absent. The lanes are parallel and spaced apart from one another. The lanes may be configured to extend in one direction only or extend in two directions such that each lane crosses one or more other lanes in a grid fashion. The lanes allow for control of the direction in which cleaning solutions, along with residual solder, solder paste, and flux, flow between the blank package 110 and the PCB 12. The lanes may be created by etching, machining, laser cutting, or the like.

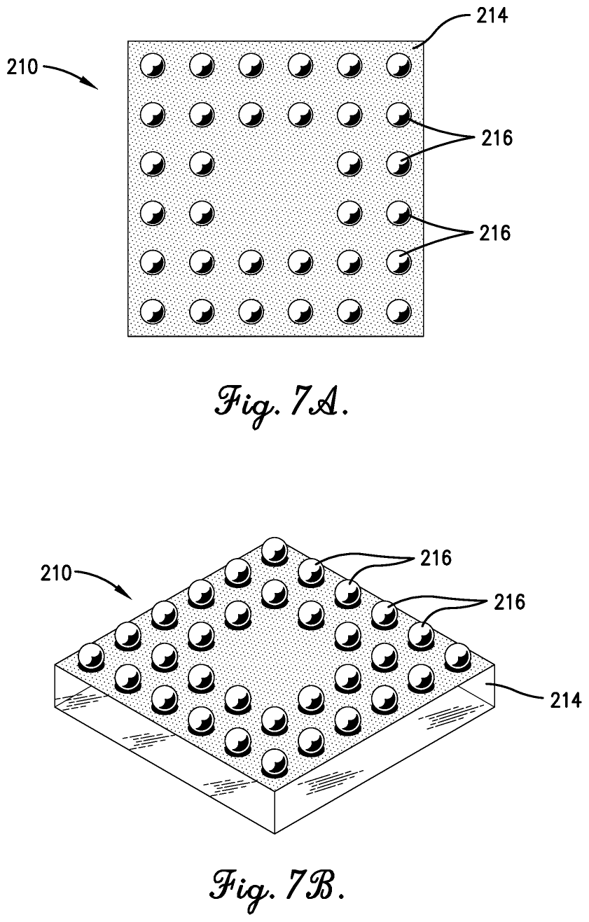

Referring to FIGS. 7A and 7B, still other embodiments of the blank package 210 include a body 214 and a plurality of conductive pads 216. The conductive pads 216 are the same as, or substantially similar to, the conductive pads 16. The body 214 is similar to the body 14, except that the bottom surface is not smooth. The bottom surface has a rough or coarse finish that gives it a diffuse, frosted, or somewhat opaque appearance. The bottom surface may be etched, machined, laser treated, or the like to create the rough finish before the conductive pads 216 are formed thereon. The rough finish of the bottom surface gives the bottom surface a diffuse appearance when the blank package 210 is soldered to the PCB 12 cleanly and there is no residue from cleaning solutions, solder, solder paste, or flux in contact with the bottom surface. However, any residue in contact with the bottom surface changes the index of refraction of the bottom surface in those areas where residual contact is made so that those areas are more transparent, or at least visibly different from the areas where nothing is in contact with the bottom surface.

In usage, at least one extra PCB 12 is fabricated for a standard production run. The PCB 12 may have nearly any intended usage or application such as in an appliance, a TV, a computer, an automotive control system, a smartphone, or the like. Ideally, one blank package 10, 110, or 210 is created for each functional package on the PCB 12. Alternatively, one blank package 10, 110, or 210 is created for at least a portion of the functional packages on the PCB 12. The blank packages 10, 110, or 210 are placed on one of the PCBs 12, and the PCB 12 with the blank packages 10, 110, or 210 undergoes the same electrical connection process using solder and flux as the functional PCBs do. Afterward, the PCB 12 with the blank packages 10, 110, or 210 undergoes the same cleaning process as the functional PCBs do. The PCB 12 with the blank packages 10, 110, or 210 may be visually inspected after the electrical connection (solder reflow) process, the cleaning process, or both.

Using visibly transparent blank packages 10, 110, or 210 in place of functional integrated circuit packages, such as QFN and BGA packages, it is possible to see to the solder connections in a way that is otherwise impossible. So the solder reflow process results can be inspected. In addition, the results of the cleaning process can be examined. It can be determined whether residue of both processes is being removed from the space between the bottom of the blank package 10 and the top surface of the PCB 12. Furthermore, the inspection process may be executed using an automated optical inspection system. Using artificial intelligence, the automated optical inspection system may be trained to identify blank packages 10, 110, or 210 under which there is residue or contamination. If the blank packages 210 are used on the PCB 12, the diffuse bottom surface of the blank package 210 provides a greater visible difference between residue being present and residue being absent, which may result in lower resolution imaging being used with the automated optical inspection system.

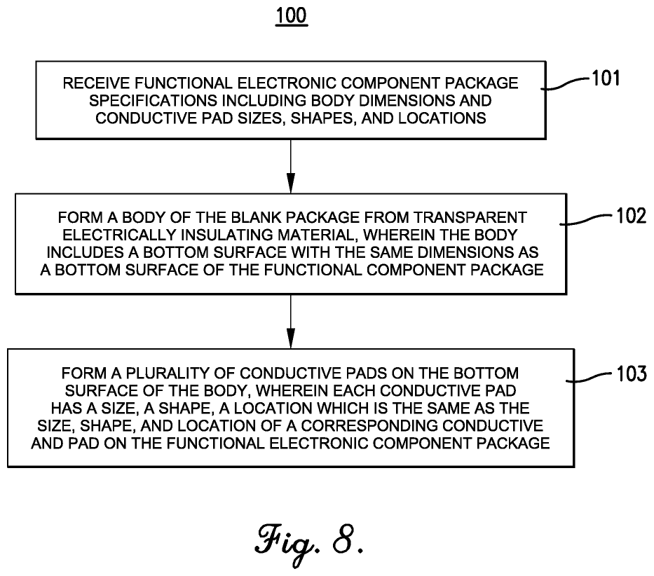

FIG. 8 depicts a listing of at least a portion of the steps of an exemplary method 100 of forming a blank package 10, 110, or 210 that mimics an electronic component package for providing visual inspection of a PCB 12. The steps may be performed in the order shown in FIG. 8, or they may be performed in a different order. Furthermore, some steps may be performed concurrently as opposed to sequentially. In addition, some steps may be optional or may not be performed.

Referring to step 101, functional electronic component package specifications are received, including body dimensions and conductive pad sizes, shapes, and locations. The functional electronic component package may include nearly any type of integrated circuit or discrete component package wherein pads or leads are positioned on the bottom surface of the package or leads extend outward from one or more side surfaces of the package, such as ball grid arrays, quad flat leaded or no leads, leaded or leadless chip carriers, and so forth. In some instances, simply a package identification number may be received and the specifications regarding the body and the pads may be retrieved from a database of integrated circuit package specifications. In other instances, the specifications regarding the body and the pads may be received from a manufacturer or other source. In still other instances, the dimensions, sizes, and locations of a specific package may be measured and recorded.

Referring to step 102, a body 14, 114, or 214 of the blank package 10, 110, 210 is formed from transparent electrically insulating material, wherein the body 14, 114, or 214 includes a bottom surface with the same, or similar, dimensions as a bottom surface of the functional component package. The body 14, 114, or 214 may be formed from various types of glass, such as silicate glass or borosilicate glass. The body 14, 114, or 214 is transmissive to light in the visible spectrum, i.e., ranging from approximately 400 nanometers (nm) to approximately 700 nm—meaning that visible light passes through the body 14, 114, or 214. Preferably, the material of the body 14, 114, or 214 is capable of withstanding high temperature. The body 14, 114, or 214 is typically solid with a box structure having a top surface, a bottom surface, and four side surfaces. However, the body 14, 114, or 214 may be configured to mimic or imitate nearly any geometry.

In some embodiments, the bottom surface of the body 214 is additionally processed to have a rough or coarse finish that gives it a diffuse, frosted, or somewhat opaque appearance. The bottom surface may be etched, machined, or laser treated to create the rough finish.

In addition, a plurality of bodies 14, 114, or 214 may be formed from a single block of glass material.

Referring to step 103, a plurality of conductive pads 16, 116, or 216 is formed on the bottom surface of the body 14, 114, or 214. The conductive pads 16, 116, or 216 are positioned on the bottom surface of the body 14, 114, or 214 and/or extend outward from one or more side surfaces of the body 14, 114, or 214. Each conductive pad 16, 116, or 216 corresponds to a successive one of the conductive pads of the electronic component package. Each conductive pad 16, 116, or 216 also has a size, a shape, and a location which is the same as, or similar to, a size, a shape, and a location, respectively, of a corresponding conductive pad or electrode on the electronic component package that the blank package 10, 110, or 210 is mimicking or imitating.

Each conductive pad 16, 116, or 216 may be formed by using physical vapor deposition, electroplating, or a combination thereof. Each conductive pad 16, 116, or 216 may include a plurality of layers, including a first layer which contacts the bottom surface of the body 14, 114, or 214 and is formed from a metal or metal alloy that adheres well to glass-type materials.

In exemplary embodiments, the conductive pads 16, 116, or 216 may be formed using the following process. Using physical vapor deposition techniques, such as sputtering, a layer of titanium, approximately 100 nanometers (nm) thick, may be deposited on the bottom surface of the body 14, 114, or 214. A layer of nickel, approximately 500 nm thick, may be deposited on the layer of titanium, and a layer of gold, approximately 400 nm thick, may be deposited on the layer of nickel. Using photopatterning and etching techniques, a portion of the layers of metals may be removed in order to form the conductive pads 16, 116, or 216.

In some embodiments, at least a portion of the conductive pads 116 are additionally processed to create a hatch pattern in the metal layer(s). Some conductive pads 116 include a plurality of narrow lanes or channels that extend across the conductive pad 116 fully along one or more dimensions in which the metal is absent. The lanes are parallel and spaced apart from one another. The lanes may be configured to extend in one direction only or extend in two directions such that each lane crosses one or more other lanes in a grid fashion. The lanes allow for control of the direction in which cleaning solutions, along with residual solder, solder paste, and flux, flow between the blank package 110 and the PCB 12. The lanes may be created by etching, machining, laser cutting, or the like.

In addition, the conductive pads 16, 116, or 216 for a plurality of blank packages 10, 110, or 210 may be formed on the same block of glass material using the techniques mentioned above. The block of glass may then be cut to form the individual blank packages 10, 110, or 210.

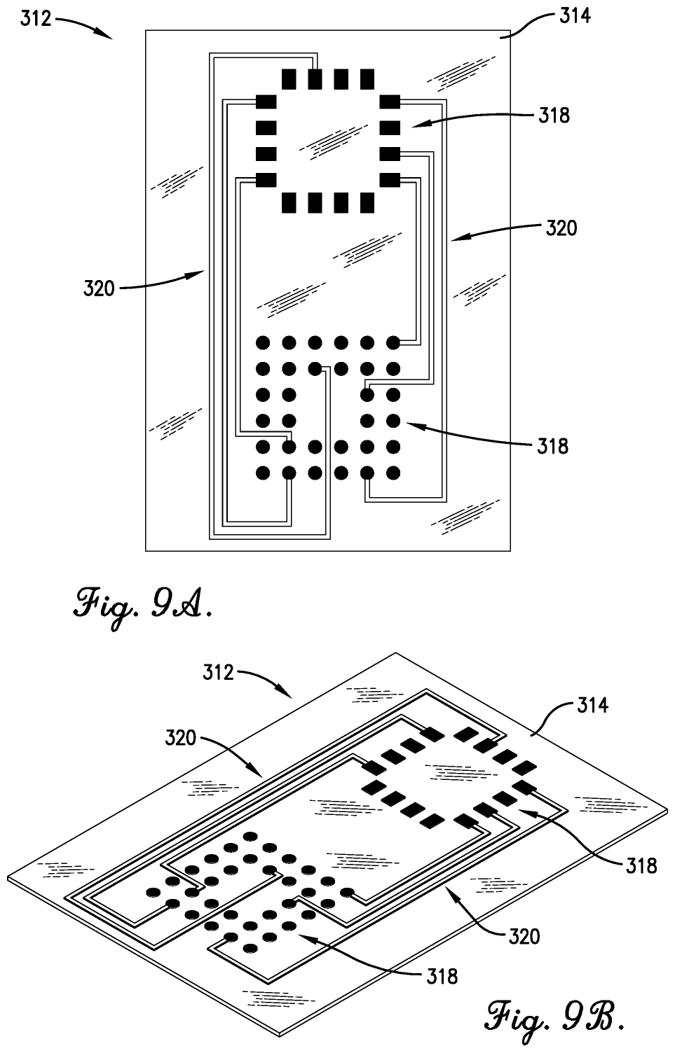

Referring to FIGS. 9A, 9B, 10A, 10B, 11A, and 11B, a transparent printed circuit board (PCB) 312, constructed in accordance with various embodiments of the current invention, for mimicking an actual printed circuit board is shown. The transparent PCB 312 broadly comprises a body 314, a plurality of package footprints 318 and a plurality of conductive traces 320. The body 314 is formed from rigid, generally transparent, or translucent, electrically insulating material including various types of glass, such as silicate glass or borosilicate glass. The body 314 typically has a quadrilateral shape with a top surface, a bottom surface, and four edges. The body 314 also generally has a thickness that is small compared with the area of the top and bottom surfaces.

Each package footprint 318 includes the land (or pad) placement for a package 310. Thus, each package footprint 318 includes a plurality of lands (pads) with a quadrilateral or circular shape arranged in nearly any type of configuration such as flat packages, ball grid arrays, leaded chip carriers, leadless chip carriers, as well as through-hole packages such as pin grid arrays and in line packages, and the like. The lands are configured to receive the conductive pads of the package 310.

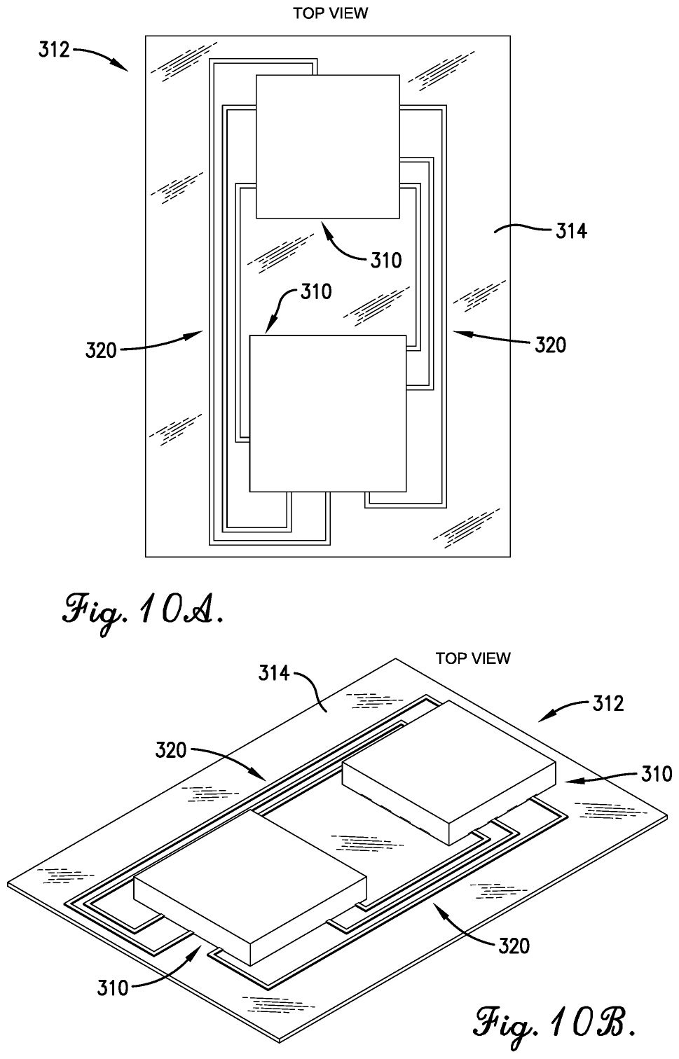

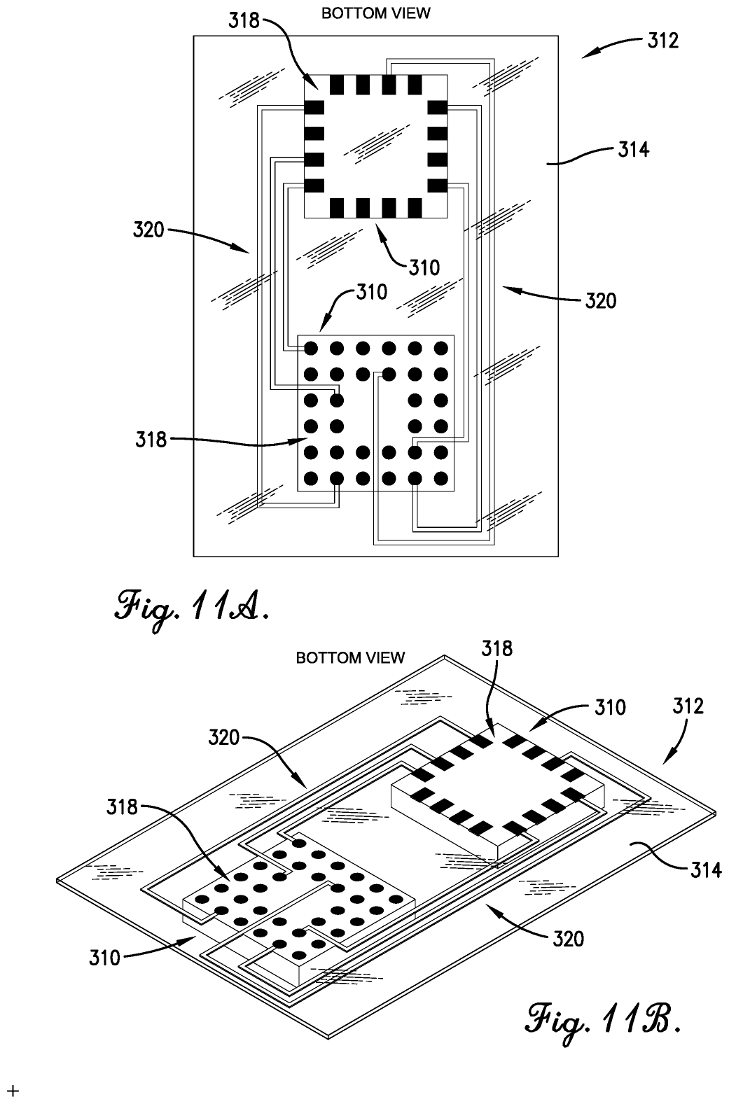

The package 310 may be an actual functional electronic component package, such as for a microprocessor, etc., or may be a blank package, such as the blank package 10, the blank package 110, or the blank package 210. Thus, the package 310 includes a plurality of conductive pads positioned on the bottom surface of the package 310 and/or extend outward from one or more side surfaces of the package 310. Exemplary packages 310 shown in FIGS. 10A, 10B, 11A, and 11B are functional integrated circuit packages.

The conductive traces 320 may carry or convey electronic signals or may provide electrical power (i.e., electric voltage and electric current) and electrical ground. The conductive traces 320 may electrically connect one or more lands on one package footprint 318 to one or more lands on one or more other package footprints 318 or to components or devices off of the transparent PCB 312. Thus, the transparent PCB 312 may further include a plurality of conductive terminals (not shown in the figures). The conductive terminals may be positioned at one or more edges of the body 314 to accommodate and connect to edge connectors or at other locations on the body 314 to accommodate and connect to other connectors such as headers, jumpers, ribbon connectors, sockets, and the like.

The package footprints 318, including the lands, and the conductive traces 320 are formed from electrically conductive material such as metals and/or metal alloys. In some embodiments, the package footprints 318 and the conductive traces 320 may be formed from a plurality of layers of metals and/or metal alloys. For example, the package footprints 318 may be formed from a stack of metals including titanium (in contact with the body 314), nickel, and gold, and the conductive traces 320 may be formed from a stack of metals including titanium (in contact with the body 314), aluminum, titanium, nickel, and gold.

The package footprints 318, the conductive traces 320, and the conductive terminals may be positioned on the top surface, the bottom surface, or both surfaces. The transparent PCB 312 may further include a plurality of through-hole plated vias (not shown in the figures) which electrically connect one or more conductive traces 320 on one surface to one or more conductive traces 320 on the opposing surface.

The transparent PCB 312 is typically created to mimic an actual functional printed circuit board, or at least a portion of an actual function printed circuit board. Thus, the transparent PCB 312 may include the same, or similar, placement of package footprints 318 and the same, or similar, routing of the conductive traces 320 as the actual functional printed circuit board. The transparent PCB 312 may be populated with blank packages 10, 110, or 210 or with functional electronic component packages in order to observe the results of the solder process and the cleaning process. Contamination and residue can be viewed by looking through the transparent PCB 312 or through blank packages 10, 110, or 210, if they are utilized.

It is also possible that, if functional electronic component packages are used for the packages 310, then the transparent PCB 312 may be electrically connected to an electric voltage source and the electronic circuitry included in the packages may be activated. Thus, it may also be possible to determine a relationship between a performance of the circuitry and a level of cleanliness (or contamination) of the solder connections on the transparent PCB 312.

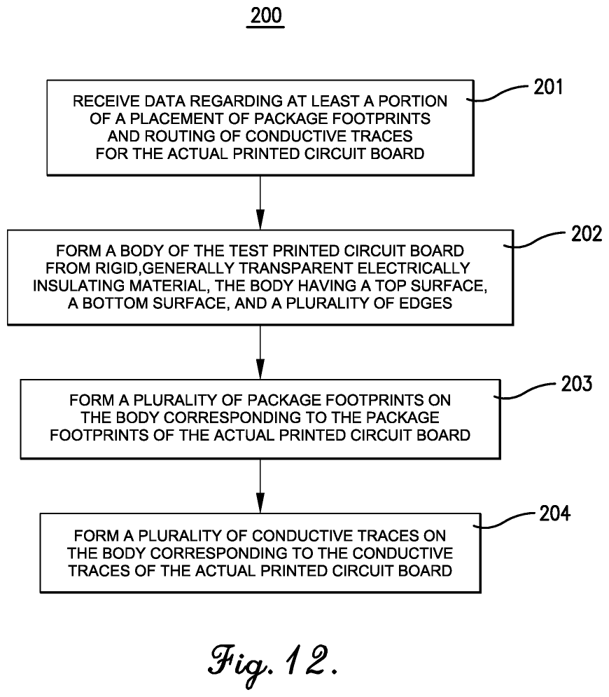

FIG. 12 depicts a listing of at least a portion of the steps of an exemplary method 200 of forming a transparent printed circuit board 312 to mimic an actual printed circuit board. The steps may be performed in the order shown in FIG. 12, or they may be performed in a different order. Furthermore, some steps may be performed concurrently as opposed to sequentially. In addition, some steps may be optional or may not be performed.

Referring to step 201, data is received regarding at least a portion of a placement of package footprints and routing of conductive traces for the actual printed circuit board. In some embodiments, the entire actual printed circuit board may be replicated. In other embodiments, only a portion of the printed circuit board may be replicated for inspecting the results of the solder and cleaning processes.

Referring to step 202, a body 314 of the transparent printed circuit board 312 is formed from rigid, generally transparent electrically insulating material. The body 314 typically has a quadrilateral shape with a top surface, a bottom surface, and four edges. The body 314 also generally has a thickness that is small compared with the area of the top and bottom surfaces. The body 314 is formed from various types of glass, such as silicate glass or borosilicate glass.

Referring to step 203, a plurality of package footprints 318 is formed on the body 314 corresponding to the package footprints of the actual printed circuit board. Each package footprint 318 includes the land (or pad) placement for a package 310. Thus, each package footprint 318 includes a plurality of lands (pads) with a quadrilateral or circular shape arranged in nearly any type of configuration such as flat packages, ball grid arrays, leaded chip carriers, leadless chip carriers, as well as through-hole packages such as pin grid arrays and in line packages, and the like. The lands are configured to receive the conductive pads of the package 310.

The package footprints 318, including the lands, are formed from electrically conductive material such as metals and/or metal alloys. In some embodiments, the package footprints 318 may be formed from a plurality of layers of metals and/or metal alloys. For example, the package footprints 318 may be formed from a stack of metals including titanium (in contact with the body 314), nickel, and gold.

In exemplary embodiments, the conductive footprints 318 may be formed using the following process. Using physical vapor deposition techniques, such as sputtering, a layer of titanium, approximately 100 nanometers (nm) thick, may be deposited on the bottom surface of the body 314. A layer of nickel, approximately 500 nm thick, may be deposited on the layer of titanium, and a layer of gold, approximately 400 nm thick, may be deposited on the layer of nickel. Using photopatterning and etching techniques, a portion of the layers of metals may be removed in order to form the conductive footprints 318.

Referring to step 204, a plurality of conductive traces 320 is formed on the body 314 corresponding to the conductive traces of the actual printed circuit board. The conductive traces 320 may carry or convey electronic signals or may provide electrical power (i.e., electric voltage and electric current) and electrical ground. The conductive traces 320 may electrically connect one or more lands on one package footprint 318 to one or more lands on one or more other package footprints 318 or to components or devices off of the transparent PCB 312. Thus, the transparent PCB 312 may further include a plurality of conductive terminals (not shown in the figures). The conductive terminals may be positioned at one or more edges of the body 314 to accommodate and connect to edge connectors or at other locations on the body 314 to accommodate and connect to other connectors such as headers, jumpers, ribbon connectors, sockets, and the like.

The conductive traces 320 are formed from electrically conductive material such as metals and/or metal alloys. In some embodiments, the conductive traces 320 may be formed from a plurality of layers of metals and/or metal alloys. For example, the conductive traces 320 may be formed from a stack of metals including titanium (in contact with the body 314), aluminum, titanium, nickel, and gold.

In exemplary embodiments, the conductive traces 320 may be formed using the following process. Using physical vapor deposition techniques, such as sputtering, a layer of titanium, approximately 100 nanometers (nm) thick, may be deposited on the bottom surface of the body 314. A layer of aluminum, approximately 1000 nm thick, may be deposited on the layer of titanium, a layer of titanium, approximately 100 nm thick, may be deposited on the layer of aluminum, a layer of nickel, approximately 500 nm thick, may be deposited on the layer of titanium, and a layer of gold, approximately 375 nm thick, may be deposited on the layer of nickel. Using photopatterning and etching techniques, a portion of the layers of metals may be removed in order to form the conductive traces 320.

In addition, holes my be drilled in the body 314 in order to create through-holes vias to electrically connect one or more conductive traces 320 on one surface to one or more conductive traces 320 on the opposing surface. Holes may also be drilled for through-hole package footprints 318 to accommodate through-hole electronic packages, such as pin grid array. The holes may be drilled using a pulsed laser or electron beam system. As an example, a femtosecond pulsed laser may be used for drilling the holes. After the holes are drilled, the holes may be plated with electrically conductive material using electroplating techniques.

### Additional Considerations

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A blank package for mimicking an electronic component package, the blank package comprising:
a body formed from generally transparent electrically insulating material, the body having a top surface, a bottom surface, and a plurality of side surfaces, the bottom surface having a shape and dimensions that are similar to a bottom surface of the electronic component package; and
a plurality of conductive pads formed from electrically conductive material and attached to the body, each conductive pad corresponding to a successive one of the conductive pads of the electronic component package and each conductive pad having features that are similar to features of the corresponding conductive pad of the electronic component package.

2. The blank package of claim 1, wherein the body is formed from borosilicate glass.

3. The blank package of claim 1, wherein the bottom surface of the body has a rough finish which gives the bottom surface a diffuse appearance.

4. The blank package of claim 1, wherein each conductive pad has a size, a shape, and a location which is the same as a size, a shape, and a location, respectively, of the corresponding conductive pad of the electronic component package.

5. The blank package of claim 1, wherein a portion of the conductive pads include a plurality of parallel lanes in which the electrically conductive material is absent.

6. The blank package of claim 1, wherein each conductive pad is formed from a plurality of layers of metal.

7. The blank package of claim 6, wherein the layers of metal include a layer of titanium in contact with the body, a layer of nickel on top of the layer of titanium, and a layer of gold on top of the layer of nickel.

8. A method of forming a blank package that mimics an electronic component package, the method comprising:
receiving functional electronic component package specifications including body dimensions and conductive pad sizes, shapes, and locations;
forming a body of the blank package from transparent electrically insulating material, wherein the body includes a bottom surface having a shape and dimensions that are similar to a bottom surface of the electronic component package; and
forming a plurality of conductive pads on the body from electrically conductive material, each conductive pad corresponding to a successive one of the conductive pads of the electronic component package and each conductive pad having features that are similar to features of the corresponding conductive pad of the electronic component package.

9. The method of claim 8, wherein the body is formed from borosilicate glass.

10. The method of claim 8, further comprising processing the bottom surface to have a rough finish which gives the bottom surface a diffuse appearance.

11. The method of claim 8, wherein each conductive pad has a size, a shape, and a location which is the same as a size, a shape, and a location, respectively, of the corresponding conductive pad of the electronic component package.

12. The method of claim 8, wherein a portion of the conductive pads include a plurality of parallel lanes in which the electrically conductive material is absent.

13. The method of claim 8, wherein each conductive pad is formed from a plurality of layers of metal.

14. The method of claim 13, wherein the layers of metal include a layer of titanium in contact with the body, a layer of nickel on top of the layer of titanium, and a layer of gold on top of the layer of nickel.

15. A transparent printed circuit board for mimicking an actual printed circuit board, the transparent printed circuit board comprising:
a body formed from rigid, generally transparent electrically insulating material, the body having a top surface, a bottom surface, and a plurality of edges;
a plurality of package footprints formed from electrically conductive material and positioned on the body, the package footprints corresponding to at least a portion of a plurality of package footprints of the actual printed circuit board; and
a plurality of conductive traces formed from electrically conductive material and positioned on the body, the conductive traces corresponding to at least a portion of a plurality of conductive traces of the actual printed circuit board.

16. The transparent printed circuit board of claim 15, wherein the body is formed from borosilicate glass.

17. The transparent printed circuit board of claim 15, wherein each package footprint includes a plurality of lands formed from a plurality of layers of metal.

18. The transparent printed circuit board of claim 17, wherein the layers of metal include a layer of titanium in contact with the body, a layer of nickel on top of the layer of titanium, and a layer of gold on top of the layer of nickel.

19. The transparent printed circuit board of claim 15, wherein each conductive trace is formed from a plurality of layers of metal.

20. The transparent printed circuit board of claim 19, wherein the layers of metal include a first layer of titanium in contact with the body, a layer of aluminum on top of the first layer of titanium, a second layer of titanium on top of the layer of aluminum, a layer of nickel on top of the second layer of titanium, and a layer of gold on top of the layer of nickel.
